(19) United States
(12) Patent Application Publication
(10) Pub. No.: US 2008/0197461 A1
(43) Pub. Date: Aug. 21, 2008

(54) Apparatus for wire bonding and integrated circuit chip package

(75) Inventors: Chen-Hua Yu, Hsinchu (TW); Hui-Lin Chang, Hsinchu (TW); Yung-Cheng Lu, Taipei (TW); Mirng-Ji Lii, Hsinchu (TW); Yung-Ching Chen, Taichung (TW)

Correspondence Address: BIRCH, STEWART, KOLASCH & BIRCH, LLP, P.O. BOX 747, FALLS CHURCH, VA, 22040-0747, US

(73) Assignee: TAIWAN SEMICONDUCTOR MANUFACTURING CO.,LTD.

(21) Appl. No.: 11/706,193

(22) Filed: Feb. 15, 2007

(51) Int. Cl. H01L 21/60; B23K 37/00; H01L 23/495

(52) U.S. Cl. 257/673; 228/4.5; 438/123; 257/E23.033; 257/E21.506

(57) ABSTRACT

An apparatus for wire bonding and a capillary tool thereof are provided. An exemplary embodiment of a capillary tool capable of a wire bonding comprises a body having a first internal channel of a first diameter for accommodating a flow of a conductive wire. A compressible head is connected to the body, having a second internal channel of a second diameter for accommodating the flow of the conductive wire, wherein the first diameter is fixed and the second diameter is variable, the second diameter is not more than the first diameter and a diameter the conductive wire flowed through the compressible head is adjustable. An integrated circuit (IC) package is also provided.

### BACKGROUND

The invention relates to semiconductor fabrication, and more particularly to an apparatus for wire bonding and an integrated circuit chip package formed thereby.

Integrated circuit (IC) chip packages are typically formed by mounting an integrated circuit (IC) chip on a lead frame and coupling these two elements to form a package. The IC chip and lead frame may be encapsulated. The IC chip typically includes a plurality of bond pads which may be positioned about a perimeter of the chip according to a predetermined spacing therebetween. The lead frame typically includes a number of lead fingers about a perimeter thereof.

In order to electrically couple the IC chip to the lead fingers of the lead frame, a wire bonding technique is often used. An apparatus for wire bonding may have a spool of bonding wire mounted on the machine. The bonding wire may be threaded through a capillary tool which is mounted to a horn of the apparatus. The horn may be manipulated to move the capillary tool both vertically and horizontally.

FIG. 1 and FIG. 2 are schematic diagrams showing a portion of an integrated circuit chip (IC) package 10 having an IC chip 12 mounted on a lead frame 14 for coupling to external circuitry. FIG. 1 is a schematic top view and the lead frame now includes a paddle 16 to which the IC chip 12 is secured by epoxy resin, and a plurality of lead frame fingers 18 which extend from a dam portion 20 toward the paddle 16 to receive a conductive wire from the IC chip. The IC chip 12 is now formed with a number of bond pads 22 positioned around a perimeter of the chip according to a spacing 24 therebetween. The bond pads 22 are now illustrated as, for example, a square pad having a width 26. Typically, the width 26 of the bond pads 22 is about 5˜100 μm and the spacing 24 therebetween is about 5˜100 μm. A conductive bond 40 is formed between one of the bond pads 22 and one of the lead frame fingers 18, including a ball portion 30 formed over the bond pad 22, a wedge bond portion 32 formed over the lead frame finger 18, and a conductive wire 28 connected therebetween, thereby forming an electrical connection between the bond pad and the lead frame.

FIG. 2 is a schematic cross section of an area 50 in FIG. 1, illustrating the conductive bond 40 connecting one of bond pads 22 of the IC chip 12 and one of the lead frame fingers 18 of the lead frame 14. The conductive bond 40 bonded between an IC chip 12 and the lead frame finger 18 is generally accomplished by “ball/wedge” bonding. According to this technique, the conductive wire 28 is first held in a capillary tool 44 of an apparatus for wire bonding and is then projected beyond the end of the tool. The capillary tool 44 forms part of the apparatus for wire bonding in which the apparatus is appropriately mounted and positioned over the bond pad 22 of the IC chip 12 mounted on the paddle 16 and has an inner channel 46 of a uniform diameter. As shown in FIG. 2, the ball portion 30 is formed of same conductive material as that of the conductive wire 28 at one end of the conductive wire 28 by melting thereof by an energy such as a hydrogen gas flame torch or by electric arc discharge (both not shown). After rehardening the ball portion 30, the ball end of the conductive wire 28 is brought into intimate contact with the bond pad 22 and the ball portion 30 of the conductive bond 40 is formed on the pad 22 by, for example, thermocompression bonding applying a specified force and temperature for a specified period of time. Metallic welding and diffusion combine to form this basic bond. Alternatively, ultrasonic bonding or other form of welding may be used. The capillary tools 44 are then moved relative to each other for bonding of the conductive wire 28 on the lead frame finger 18. At this location, the wedge bond portion 32 between the conductive wire 32 and lead frame finger 18 is generally formed and the conductive wire 28 is severed below the bonding tool at the weld. The wedge bond portion 32 is formed by thermocompression or ultrasonic bonding with the edge of the capillary tool 30 bearing against the conductive wire 28 and lead frame finger 18. In this manner, a conductive wire connection is established between the bond pads 22 of the IC chip 12 and the lead frame 14 for coupling to external circuitry.

Nevertheless, the continuing trend in semiconductor and integrated circuit industries is to develop and manufacture smaller components. This trend has resulted in integrated circuits and semiconductor devices having higher density due to an increased number of components coexisting in smaller physical areas. This downsizing has directly affected the location, number, and size of bond pads for electrical connections for these devices. Therefore, wire bonding techniques have been developed to accommodate smaller bond pad sizes as well as bond pad sizes with fine spacing therebetween through, for example, usage of conductive wires with reduced diameter, such as conductive wires having a diameter of about 0.8 mil or less. However, such reduction in conductive wire diameter results in poor IR performance thereof because electrical resistance of a conductive line increases when a diameter thereof is reduced. Reliability of diameter reduced conductive wire is thus affected.

### SUMMARY

Thus, a reliable wire bonding apparatus for providing wire bonds on bond pads with reduced spacing therebetween is desirable. An apparatus for wire bonding and a capillary tool used therein are provided. An integrated circuit (IC) package and a method for fabricating the same are provided.

An exemplary embodiment of a capillary tool capable of a wire bonding comprises a body having a first internal channel of a first diameter for accommodating a flow of a conductive wire. A compressible head is connected to the body, having a second internal channel of a second diameter for accommodating the flow of the conductive wire, wherein the first diameter is fixed and the second diameter is variable, the second diameter is not more than the first diameter and a diameter the conductive wire flowing through the compressible head is adjustable.

An exemplary embodiment of an apparatus for wire bonding comprises a capillary tool, an energy source, a control arm and a drive unit. The capillary tool comprises similar elements as described. The energy source is capable of providing energy to a tip of the capillary tool and the control arm is capable of moving the capillary tool in a bonding direction. The drive unit is capable of selectively moving the control arm.

An exemplary embodiment of an integrated circuit (IC) package comprises a lead frame comprising at least one paddle and one frame finger. An integrated circuit chip is positioned over the paddle, wherein the IC chip comprises a plurality of pads thereover. A conductive wire electrically connects one of the pads and the frame finger, wherein the conductive wire comprises a ball portion with a first diameter, a line portion with a second diameter and a neck portion with a third diameter between the line portion and the ball portion, and the third diameter is smaller than the first and/or second diameter.

An exemplary method for fabricating an integrated circuit package comprises providing a lead frame comprising at least one paddle and one frame finger. An integrated circuit chip is provided over the paddle, wherein the IC chip comprises a plurality of pads thereover. A conductive wire bond electrically connects one of the pad and the frame finger, wherein the conductive wire comprises a ball portion with a first diameter, a line portion with a second diameter and a neck portion with a third diameter between the line portion and the ball portion, and the third diameter is smaller than the first and/or second diameter.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic top view showing a part of a conventional integrated circuit chip (IC) package;

FIG. 2 is a schematic cross section partially showing an area of the integrated circuit chip (IC) package illustrated in FIG. 1;

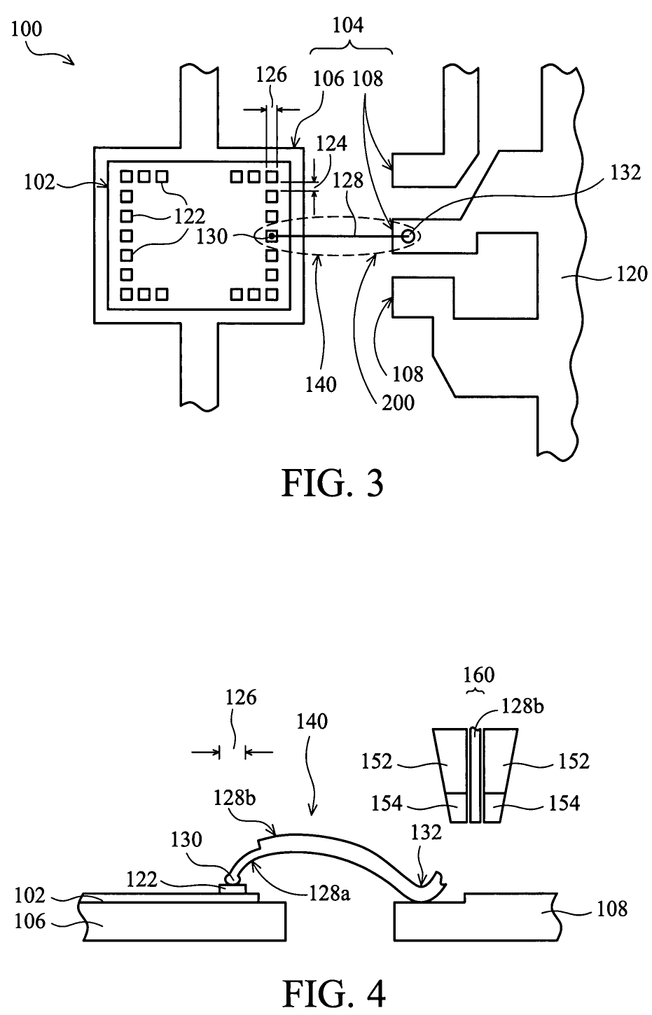

FIG. 3 is a schematic top view showing a part of an integrated circuit chip (IC) package according to an embodiment of the invention;

FIG. 4 is a schematic cross section showing an area of the integrated circuit chip (IC) package illustrated in FIG. 3;

FIG. 5 is a schematic diagram showing an apparatus for wire bonding according to an embodiment of the invention; and

FIGS. 6a-6e are schematic diagrams showing fabrication steps of a method for forming a wire bonding according to an embodiment of the invention, respectively.

### DESCRIPTION

The following description is of the best-contemplated mode of carrying out the invention. This description is made for the purpose of illustrating the general principles of the invention and should not be taken in a limiting sense. The scope of the invention is best determined by reference to the appended claims.

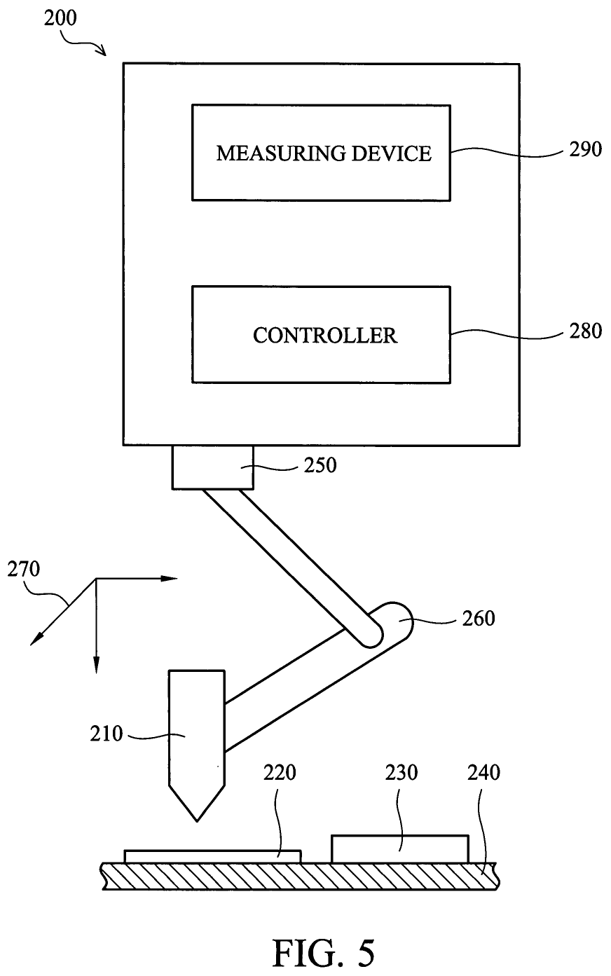

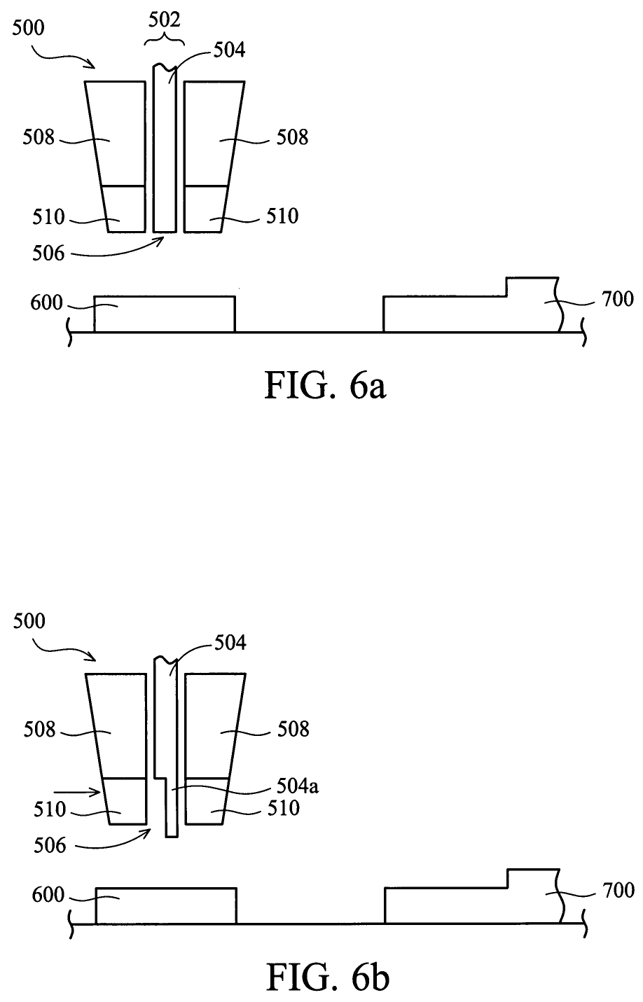

FIG. 3 and FIG. 4 are schematic diagrams showing a portion of an exemplary integrated circuit chip (IC) package 100 having an IC chip 102 mounted on a lead frame 104 for coupling to external circuitry (not shown). FIG. 3 is a schematic top view and the lead frame 104 now includes a paddle 106 to which the IC chip 102 is secured by epoxy resin and a plurality of lead frame fingers 108 which extend from a dam portion 120 toward the paddle 106 to receive a conductive bond from the IC chip 102.

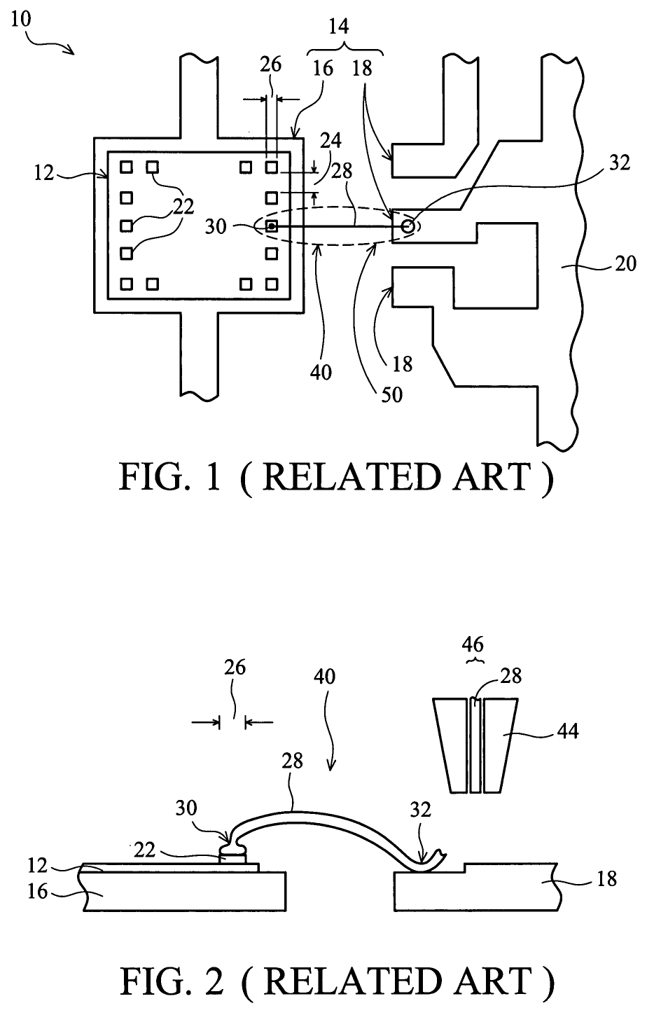

With the trend in the semiconductor and integrated circuit industries of developing and manufacturing smaller components, the IC chip 100 is now formed with semiconductor devices (not shown) having higher density and the location, number, and size of bond pads for electrical connections for these devices are provided in a greater number and a finer spacing compared with those of the conventional IC chip illustrated in FIG. 1. The IC chip 102 is now formed with a greater number of bond pads 122 positioned around a perimeter of the chip according to a finer spacing 124 therebetween. The bond pads 122 are now illustrated as, for example, a square pad having a width 126. The width 126 of the bond pads 22 is now reduced to about 5˜50 μm and the spacing 124 therebetween is also reduced to about 5˜50 μm, thereby allowing formation of greater number of bond pads 122 over the IC chip 102. As shown in FIG. 3, a conductive bond 140 can be formed between one of the bond pads 122 and one of the lead frame fingers 108, having a ball portion 130 formed over the bond pad 122, a wedge bond portion 132 formed over the lead frame finger 108 and a conductive wire 128 connecting the ball portion 130 and the wedge bond portion 132.

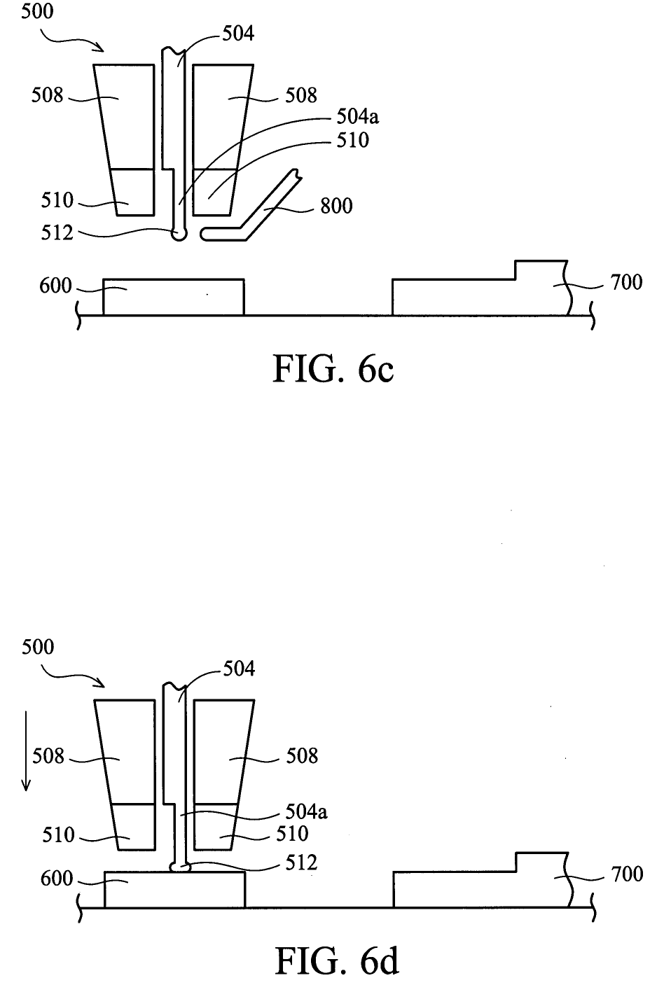

FIG. 4 is a schematic cross section of an area 200 in FIG. 1, illustrating the conductive bond 140 connecting the bond pad 122 and the lead frame finger 108. The conductive bond 140 is now formed with a conductive wire 128 electrically connecting the IC chip 102 and the lead frame finger 108 as a wire of non-uniform diameter. The conductive wire 128 includes a main portion 128b of a greater diameter and a neck portion 128a of a smaller diameter. Formation of the conductive bond 140 can be accomplished by, for example, “ball/wedge” bonding. According to this technique, the main portion 128b of the conductive wire 128 is first held in a capillary tool 150 of an apparatus for wire bonding (see FIG. 5) projecting beyond the end of the tool. The capillary tool 150 forms part of the apparatus for wire bonding in which the apparatus is appropriately mounted and positioned over the bond pad 122 of the IC chip 102 mounted on the paddle 106. As shown in FIG. 4, the capillary tool 150 is formed of a main body 152 and a compressible head 154, having an inner channel of a uniform diameter 160 for accommodating the main portion 128b of the conductive wire 128 and a reduced diameter (not shown) for accommodating the reduced portion 128a of the conductive wire 128. The compressible head 154 first compress a portion of the main portion 128 of the conductive wire 128 to thereby form the neck portion 128a of a reduced diameter. The neck portion 128a protrudes slightly from an opening adjacent the compressible head 154. Next, the ball portion 130 is formed at one end of the neck portion 128a of the conductive wire 128 by an energy source such as a hydrogen gas flame torch or by electric arc discharge (both not shown), thereby forming a ball (not shown) of reduced diameter for the bond pad 122. After rehardening the ball portion 130, the ball end of the wire (not shown) is brought into close contact with the pad 122 and the ball portion 130 of the conductive bond 140 is formed on the conductive pad 122 by, for example, thermocompression bonding applying a specified force and temperature for a specified period of time. Metallic welding and diffusion combine to form this basic bond. Alternatively, ultrasonic bonding or another form of welding may be used. Next, the compressible head 154 maintains at a uncompress position and the capillary tool 150 is then moved relative to each other for bonding of the main portion 128b of the conductive wire 128 on the lead frame finger 108. At this location, the wedge bond portion 132 between the main portion 128b of the conductive wire 128 and lead frame finger 108 is formed and the main portion of the conductive wire 128 is severed below the bonding tool at the weld. The wedge bond portion 132 is formed by thermocompression or ultrasonic bonding with the edge of the capillary tool 150 bearing against the conductive wire 128 and the lead frame finger 108. In this manner, a conductive wire connection is established between one of the bond pads 122 of the IC chip 102 and the lead frame 104 for coupling to external circuitry.

FIG. 5 shows a schematic diagram of an exemplary apparatus. 200 for wire bonding. As shown in FIG. 5, the apparatus 200 includes a wire bonding device 210, such as the capillary tool 150 illustrated in FIG. 4, which is controllably positioned relative to an integrated circuit chip 220 and a lead frame 230 positioned over a package substrate 240. The bonding device 210 is capable of forming wire bonds at a plurality of bonding positions on the IC chip 220. The apparatus 200 further comprises a drive unit 250, such as a motor, for selectively moving a control arm 260 which in turn moves the bonding device 210 in any direction represented by multiple arrows 270. The apparatus 200 may also comprise a measuring device 280 for measuring movements of the wire bonding device 210, and a controller 290 for controlling the drive unit 250.

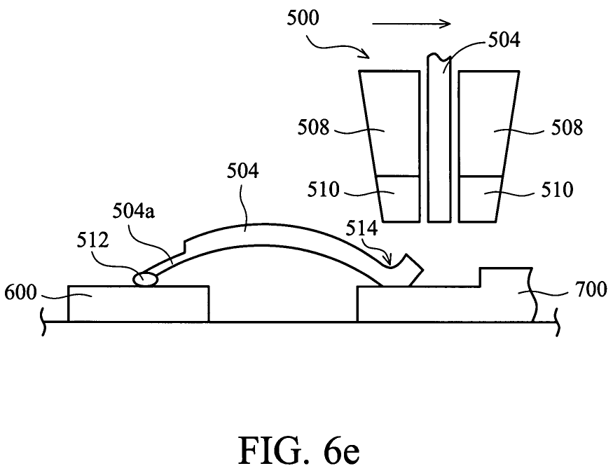

FIGS. 6a-6e are schematic diagrams showing individual fabrication steps of a method for forming a wire bonding according to an embodiment of the invention. As shown in FIG. 6a, a bonding device such as a capillary tool 500 for wire bonding device 200 of the apparatus shown in FIG. 5 is provided. The capillary tool 500 is similar to that illustrated in FIG. 4 and has an internal channel 502 for accommodating a conductive wire 504, and an opening 506 to introduce the conductive wire 504 to an intended surface, such as a top surface of a bond pad 600 and/or a lead frame 700. The capillary tool 500 is formed with a main body 508 and a compressible head 510. At least one side of the compressible head 510 is removable toward another side thereof, thereby reducing the diameter of the conductive wire 504.

As shown in FIG. 6b, during a wire bonding process, the conductive wire 504 is fed through the inner channel 502 and out of the opening 506. The conductive wire 506 is preferably a gold wire, however, any suitable conductive material such as aluminum wire, lead wire, or iron wire can be substituted. Prior to feeding the conductive wire 504 out of the opening 506, the portion of the conductive wire 504 adjacent to the opening 506 is first compressed by the compressible head 510 to thereby form a portion thereof in a reduced diameter and partially protruding over the opening 506, titled as 504a. The above compression can be achieved by movement of at least one side or both sides of the compressible head 510. As shown in FIG. 6b, the conductive wire 504 is now formed with a reduced portion at an end thereof adjacent to the compressible head 510 of the capillary tool 500 and the reduced portion 504a is now off-axial with the conductive layer 504 but is not limited thereto. Once the conductive wire 504 is compressed through movements of both sides of compressible head 510, the reduced portion 504a of the conductive wire 504 may be co-axial with the other portion of the conductive wire 504 and is not illustrated here, for simplicity.

As shown in FIG. 6c, a ball 512 is formed at the tip of the protrusion of the reduced portion 504a of the conductive wire 504 by an energy source 800 such as an electric discharge of a torch electrode, or by heating the tip of the capillary tool 500. Other methods of forming the ball 512 can also be utilized. The size of the ball 512 can be controlled by varying hardware and software of the apparatus for wire bonding and is formed with a reduced diameter. After the ball 22 is formed, the capillary tool 500 is positioned above a desired location on a top surface of the bond pad 600, as shown in FIG. 6d. The ball 512 is then forced downward to the surface by downward movement of the capillary tool 500, thereby causing the ball 512 to deform into a mass. The downward force of the capillary tool 500 can be combined with, for example, ultrasonic energy to create a bond between the ball 512 and the top surface of the bond pad 600. Thereafter, as shown in FIG. 6e, the capillary tool 500 is moved away from the top surface of the bond pad 600 causing the conductive wire 504 to continually feed through the inter channel 502 thereof and move to a bonding site on the lead frame 700. The lead frame 700 is heated to a temperature of about 150-350° C. and the conductive wire 504 is pressed against the lead frame 700 to alloy the conductive wire with lead frame 700, thereby bonding the conductive wire 504 to the lead frame 700 and forming an wedge portion 514 thereon. It is noted that the conductive wire 504 is formed with a reduced portion 504a having a diameter smaller than that thereof and the ball 512 is thus formed with a reduced diameter compared with conventional conductive ball formed in conventional wire bonding. The conductive wire 504 can be provided in a diameter of about 0.1˜1.0 mil and the reduced portion 504a is about 90% less than the diameter of the conductive wire 504. For example, the diameter of the reduced portion is less than 0.9 mil and preferably less than 0.7 mil. The diameter of the conductive wire 504 flows through the compressible head 510 is adjustable between 10 E⁻⁶˜1 mm. Since only portions of the conductive wire 504 is previously and partially size-reduced, therefore providing a conductive wire capable formed on a size-reduced bond pad, having a diameter substantially not reduced. Thus, IR performance of such conductive wires with partially reduced diameter is ensured and electrical resistances thereof will not be increased since an overall diameter thereof is not significantly reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An apparatus for wire bonding, comprising:
a capillary tool, comprising;
a body having a first internal channel of a first diameter for accommodating a flow of a conductive wire; and
a compressible head connected to the body, having a second internal channel of a second diameter for accommodating the flow of the conductive wire, wherein the first diameter is fixed and the second diameter is variable, the second diameter is not more than the first diameter and a diameter the conductive wire flowed through the compressible head is adjustable;
an energy source for providing energy to a tip of the capillary tool;
a control arm for moving the capillary tool in a bonding direction; and
a drive unit for selectively moving the control arm.

2. The apparatus as claimed in claim 1, wherein apparatus further comprising:
a controller for controlling the drive unit; and
a measuring device for measuring movements of the capillary tool.

3. The apparatus as claimed in claim 1, wherein the diameter the conductive wire flowed through the compressible head is less than 90% of the first diameter.

4. The apparatus as claimed in claim 1, wherein the diameter the conductive wire flowed through the compressible head is less than 0.9 mil.

5. The apparatus as claimed in claim 4, wherein the diameter the conductive wire flowed through the compressible head is less than 0.7 mil.

6. The apparatus as claimed in claim 1, wherein the compressible head comprises at least one movable component for squeezing the conductive wire of the fixed first diameter flowed through the body into the variable second diameter.

7. The apparatus as claimed in claim 1, wherein the diameter of the conductive wire flowed through the compressible head is adjustable between 10E⁻⁶˜1 mm.

8. An integrated circuit (IC) package, comprising:
a lead frame comprising at least one paddle and one frame finger;
an integrated circuit chip positioned over the paddle, wherein the IC chip comprises a plurality of pads thereover; and
a conductive wire electrically connecting one of the pad and the frame finger, wherein the conductive wire comprises a ball portion with a first diameter, a line portion with a second diameter and a neck portion with a third diameter between the line portion and the ball portion, and the third diameter is smaller than the first and/or second diameter.

9. The IC package as claimed in claim 8, wherein the first diameter is about 0.1˜1 mil.

10. The IC package as claimed in claim 8, wherein the second diameter is about 0.1˜1 mil.

11. The IC package as claimed in claim 8, wherein the third diameter is about 0.1˜1 mil.

12. The IC package as claimed in claim 8, wherein the pads are formed with a spacing of about 5˜50 μm therebetween.

13. The IC package as claimed in claim 8, wherein the conductive line comprises gold, aluminum, iron or alloys thereof.

14. The IC package as claimed in claim 8, wherein the conductive wire is formed by a capillary tool, comprising;
a body having a first internal channel of a fourth diameter for accommodating a flow of the conductive wire; and
a compressible head connected to the body, having a fifth internal channel of a second diameter for accommodating the flow of the conductive wire, wherein the fourth diameter is fixed and the fifth diameter is variable, the fifth diameter is not more than the fourth diameter,
wherein the neck portion of the conductive wire is formed by compressing the conductive wire by the compressible head at the third diameter.

15. A method for fabricating an integrated circuit package, comprising:
providing a lead frame comprising at least one paddle and one frame finger; providing an integrated circuit chip over the paddle, wherein the IC chip comprises a plurality of pads thereover; and
bonding a conductive wire electrically connecting one of the pad and the frame finger, wherein the conductive wire comprises a ball portion with a first diameter, a line portion with a second diameter and a neck portion with a third diameter between the line portion and the ball portion, and the third diameter is smaller than the first and/or second diameter.

16. The method as claimed in claim 14, wherein the first diameter, the second diameter and the third diameter are about 0.1˜1 mil.

17. The method as claimed in claim 14, wherein the pads are formed with a spacing of about 5˜50 μm therebetween.

18. The method as claimed in claim 14, wherein the conductive line comprises gold, aluminum, iron or alloys thereof.

19. The method as claimed in claim 14, wherein bonding the conductive wire electrically connecting one of the pad and the frame finger comprising:
providing a capillary tool, comprising;
a body having a first internal channel of a fourth diameter for accommodating a flow of the conductive wire of the second diameter; and
a compressible head connected to the body, having a second internal channel of a fifth diameter for accommodating the flow of the conductive wire, wherein the fourth diameter is fixed and the fifth diameter is variable, the fifth diameter is not more than the fourth diameter and a diameter the conductive wire flowed through the compressible head is adjustable;
setting the fifth diameter of the second internal channel as the same of the fourth diameter of the first internal channel;
feeding the conductive wire with the second diameter through the first and second internal channels;
setting the fifth diameter of the second internal channel to the third diameter, compressing the portion the conductive wire into the third diameter by the compressible head, protruding a portion thereof over the compressible head;
providing an energy to capillary tool, forming the portion of the conductive protruding over the compressible head to a ball portion of the first diameter, leaving a neck portion of the third diameter in the second internal channel;
contacting the ball portion with a top surface of the pad by moving the capillary tool, thereby connecting the integrated circuit chip and the conductive wire;
setting the fifth diameter of the second internal channel from the second diameter to the third diameter;
moving the capillary tool over a bonding site on the frame finger and continually feeding the conductive wire through the capillary tool; and
pressing the conductive wire of the second diameter against the bonding site on the lead finger to alloy the conductive wire with lead frame, thereby forming the conductive wire comprising the ball portion with a first diameter, a line portion with the second diameter and the neck portion with the third diameter between the line portion and the ball portion connecting the pad and the frame finger.
